(19) United States
(12) Patent Application Publication
(10) Pub. No.: US 2006/0157867 A1
(43) Pub. Date: Jul. 20, 2006

(54) Flip-chip package structure with direct electrical connection of semiconductor chip

(76) Inventor: Shih-Ping Hsu, Hsin-chu (TW)

Correspondence Address: SAWYER LAW GROUP LLP, P O BOX 51418, PALO ALTO, CA, 94303, US

(21) Appl. No.: 11/273,890

(22) Filed: Nov. 14, 2005

(30) Foreign Application Priority Data
Jan. 17, 2005 (TW) 094101281

(51) Int. Cl. H01L 23/48

(52) U.S. Cl. 257/778

(57) ABSTRACT

A flip-chip package structure with direct electrical connection of a semiconductor chip has at least a dielectric layer; the semiconductor chip having electrical connection pads on an active surface thereof and connecting the dielectric layer via the active surface; and at least a wiring layer formed on a side of the dielectric layer not connecting the semiconductor chip, the wiring layer electrically connecting the electrical connection pads of the semiconductor chip via a plurality of conductive electrodes formed in the dielectric layer. A non-active surface of the semiconductor chip can be exposed, the heat dissipating efficiency can be enhanced, while the overall height of the package structure can be decreased.

### FIELD OF THE INVENTION

The present invention relates to a flip-chip package structure with direct electrical connection of a semiconductor chip, and more specifically, to a thin flip-chip package structure with direct electrical connection of a semiconductor chip integrated therein.

### BACKGROUND OF THE INVENTION

With the rapid development of electronic industry, electronic products are led into a research and development direction of multi-functional and high-functional. In order to meet the requirement of high integration and miniaturization for semiconductor package, circuit boards which provide a plurality of active and passive elements and circuit connections, have evolved from single-layered to multi-layered, so that the available layout area on a circuit board is increased via interlayer connection within limited space, meeting the demand of high electronic density of integrated circuit.

However, because the increasing of conductive wiring layers and element density, heat generated from high integration semiconductor chip is greatly increased. If such heat is not dissipated duly, the semiconductor package will be over heated thus seriously affecting the life span of the chip. Currently, ball grid array (BGA) structure can not satisfy the requirement of electrical feature and heat dissipation when in the circumstance of high pin counts (1500 pins) and high frequency over 5 GHz.

Consequently, flip chip ball grid array (FCBGA) package structure is developed, as shown in FIG. 1, a prior art disclosed in U.S. Pat. No. 6,774,498 comprises a semiconductor die 10 with a plurality of semiconductor die pads 101 on the active surface thereof for providing signal input/output. A plurality of bumps 11 located on the die pads 101 electrically connect to bump pads 121a of a chip package substrate 12. The chip package substrate 12 is formed with a plurality of wiring layers 122 and insulation layers 123, wherein two wiring layers 122 are connected by conductive plugs 125. A patterned solder mask 13a is formed on the topmost wiring layer 122a of the substrate 12 for protecting the wiring layer 122a while exposing bump pads 121a.

A plurality of bump pads 121b are located on the bottommost wiring layer 122b of the chip package substrate 12, where a patterned solder mask 13b is deposited over the wiring layer 122b for protection while exposing bump pads 121b. Solder balls 14 and others electrically conductive structures of the like can be formed on the bump pads 121b.

Thus, the semiconductor die pads 101 of the semiconductor die 10 is electrically connected to the bump pads 121a of the uppermost wiring layer 122a via bumps 11 on the upper surface of the chip package substrate 12; whereas the bump pads 121b located on the bottommost wiring layer 122b of the chip package substrate 12 are electrically connected to the solder balls 14, therefore, a FCBGA packaging is fabricated.

However, during the fabrication of the FCBGA packaging, fabrication of the chip package substrate 12 is performed and another independent fabrication for electrically connecting and packaging the semiconductor chip 10 to the chip package substrate 12 is performed. The two independent fabricating procedures may cause low yield and long production cycle, and the electrical properties cannot be effectively improved after reaching a certain limited level. Although the FCBGA structure can be used in products having high pin counts and high frequency, however, the total packaging cost is considerably high, and there are still many technical limitations, particularly in terms of electrical connection, since traditionally used soldering material such as lead (Pb) will be banned due to environmental concerns and other replacing materials may not be as stable in terms of electrical, mechanical and physical properties.

The conventional separate fabricating methods for the FCBGA structure has deficiencies of low yield and long production cycle, increasing the fabricating cost and hindering enhancement of competitive edge, thus it becomes a problem urgently desired to be solved.

### SUMMARY OF THE INVENTION

Regarding the drawbacks of the above mentioned conventional technologies, the primary objective of the present invention is to provide a flip-chip package structure with direct electrical connection of the semiconductor chip to integrate the semiconductor chip and the chip carrier and electrical connections thereof.

Another objective of the present invention is to provide a flip-chip package structure with direct electrical connection of the semiconductor chip for effectively utilize the space of the structure to enhance the electrical properties of the semiconductor device.

Still another objective of the present invention is to provide a flip-chip package structure with direct electrical connection of the semiconductor chip for enhancing heat dissipating efficiency of the semiconductor chip.

Still another objective of the present invention is to provide a flip-chip package structure with direct electrical connection of the semiconductor chip for providing a thin semiconductor package.

In accordance with the above and other objectives, the present invention proposes a flip-chip package structure with direct electrical connection of at least one semiconductor chip, the structure comprises at least a dielectric layer; the semiconductor chip having electrical connection pads on an active surface thereof and connecting the dielectric layer via the active surface; and at least a wiring layer formed on a side of the dielectric layer not connected to the semiconductor chip. The wiring layer electrically connects the electrical connection pads of the semiconductor chip via a plurality of conductive electrodes formed in the dielectric layer. In addition, electrode pads are further formed on the dielectric layer at a side thereof connected to the semiconductor chip, or the conductive electrodes in the dielectric layer are exposed to electrically connecting electronic elements (such as active or passive elements). Furthermore, a plurality of conductive elements can be formed on the surface of the wiring layer for electrically connecting the semiconductor chip to external devices.

A non-active surface of the semiconductor chip is exposed to the outside, thus enhancing heat dissipating efficiency while reducing the overall height of the package structure. In addition, various kinds of electronic elements (such as active or passive elements) are connected to a side of the structure with the exposed semiconductor chip. The electronic elements can be connected to the semiconductor chip via an exposed portion of the conductive electrodes and the wiring layer, thus effectively utilizing the space of the package structure and improving the electrical properties thereof. Additionally, a plurality of conductive elements can be connected to the surface circuit of the structure for connecting the structure to external devices.

In addition, at least a wiring layer is formed directly on the active surface of the semiconductor chip according to embodiments of the present invention. A wiring layer structure electrically connects the electrical connection pads of the semiconductor chip via the conductive electrodes. A plurality of conductive elements, such as solder balls, solder pads, pins or metal bumps, can be formed on external surface of the wiring layers for connecting to external devices.

### BRIEF DESCRIPTION OF THE DRAWINGS

FIG. 1 is a sectional view of a semiconductor device disclosed in U.S. Pat. No. 6,774,498;

FIGS. 2A to 2F are section views of a flip-chip package structure with direct electrical connection of a semiconductor chip in accordance with a first embodiment of the present invention; and

FIGS. 3A to 3C are sectional views of a flip-chip package structure with direct electrical connection of a semiconductor chip in accordance with a second embodiment of the present invention.

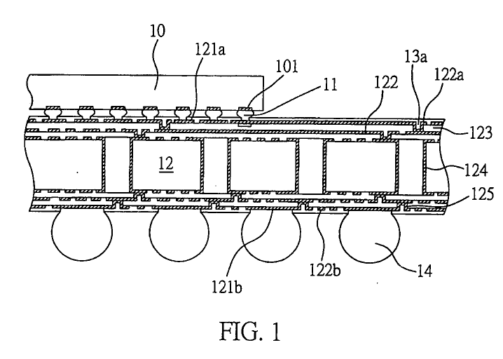

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention is also implemented and applied according to other embodiments, and details are modified based on different views and applications without departing from the spirit of the invention.

### First Embodiment

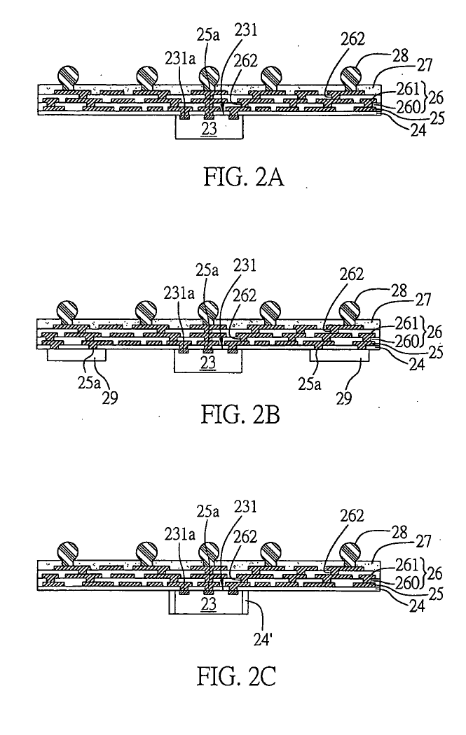

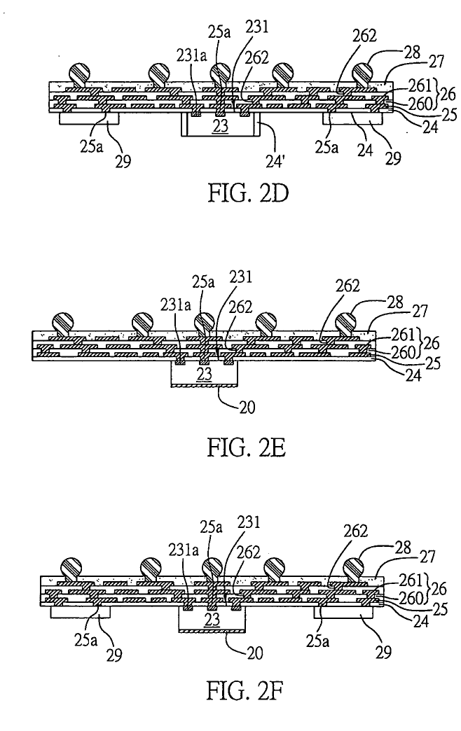

FIGS. 2A to 2D are sectional views of a flip-chip package structure with direct electrical connection of a semiconductor chip in accordance with a first embodiment of the present invention. It is to be noted that, the figures are schematic views only for showing the basic structure of the present invention. Thus, only those structures related to the present invention are illustrated in the figures. The actual quantity, shape and size can be selectively varied in accordance with different requirements.

Referring to FIG. 2A, the flip-chip package structure with direct electrical connection of semiconductor chip of the present invention comprises: at least a semiconductor chip 23, the semiconductor chip 23 having an active surface and a non-active surface, and the active surface 231 of the semiconductor chip 23 comprising electrical connection pads 231a, the semiconductor chip 23 selected to be an active element or a passive element, wherein the passive element is selected from a group consisting of resistors, capacitors and inductors; at least a dielectric layer 24 formed on the active surface 231 of the semiconductor chip 23, and the area of the dielectric layer 24 being greater than that of the active surface 231, so that the non-active surface of the semiconductor chip 23 is directly exposed; and at least a wiring layer 25 formed on a side of the dielectric layer 24 not connecting to the semiconductor chip 23, the wiring layer 25 electrically connecting the electrical connection pads 231a of the semiconductor chip 23 via a plurality of conductive electrodes 25a formed in the dielectric layer 24.

An added wiring layer structure 26 can be further formed on the dielectric layer 24 and the wiring layer 25. The added wiring layer structure 26 comprises a dielectric layer 260, a wiring layer 261 formed on the dielectric layer 260 and a conductive blind via 262 extending through the dielectric layer 260 for connecting the wiring layer 261, and the added wiring layer structure 26 also electrically connects the wiring layer 25 through conductive blind via 262. A solder mask layer 27 is formed on the outer surface of the added wiring layer structure 26, and the solder mask layer 27 defines a plurality of openings for exposing a portion of the wiring layer on the outer surface of the added wiring layer structure 26, so that a plurality of conductive elements, such as solder balls, solder pads, pins or metal bumps, are formed thereon, for electrically connecting the semiconductor chip 23 to external devices.

The semiconductor chip 23 not connecting to the surface of the dielectric layer 24 can be exposed, heat dissipating efficiency can be enhanced, and the overall height of the package structure can be decreased, thus achieving a light and thin structure.

Referring to FIG. 2B, the wiring layer 25 formed on the surface of the dielectric layer 24 comprises a plurality of conductive electrodes 25a, wherein a portion of the conductive electrodes 25a electrically connects the electrical connection pads 231a of the semiconductor chip 23, and a portion of the conductive electrodes 25a are exposed from the surface without the semiconductor chip 23 for subsequently connecting external electrical elements 29, such as active elements or passive elements, to the inner circuit via the partially exposed conductive electrodes 25a. Thus, flexibly utilizing the space of the package structure and improving the electrical properties thereof. The semiconductor chip and any external electronic elements can be firstly formed, and the aforementioned dielectric layer, wiring layer, added wiring layer structure, conductive electrodes, solder mask layer, and electrical connection structure (e.g. solder balls) can be then formed on the semiconductor chip and the external electronic elements.

Referring to FIG. 2C, a thin dielectric layer 24′ is formed on the circumference of the semiconductor chip 23 for coating and securing the semiconductor chip 23 to the bottom of the dielectric layer 24, therefore preventing the semiconductor chip 23 from being damaged by external force. The wiring layer 25 formed on the surface of the dielectric layer 24 comprises a plurality of conductive electrodes 25a, which electrically connect the electrical connection pads 231a of the semiconductor chip 23.

Referring to FIG. 2D, the thin dielectric layer 24′ is formed on the circumference of the semiconductor chip 23 in a similar way to that illustrated in FIG. 2C. Moreover, the wiring layer 25 formed on the surface of the dielectric layer 24 comprises a plurality of conductive electrodes 25a, wherein a portion of the conductive electrodes 25a electrically connects the electrical connection pads 231a of the semiconductor chip 23, and a portion of the conductive electrodes 25a are exposed from the surface without the semiconductor chip 23 for additionally connecting other external electrical elements, thus flexibly using the space of the package structure and improving the electrical properties thereof. The semiconductor chip and the external electronic elements can be firstly formed, and the aforementioned dielectric layer, wiring layer, added wiring layer structure, conductive electrodes, solder mask layer, and electrical connection structure (e.g. solder balls) can be then formed on the semiconductor chip and the external electronic elements.

Referring to FIG. 2E, a metal layer 20 is formed on a bottom side of the semiconductor chip 23 not connecting to the dielectric layer 24, wherein the metal layer 20 is made of material having high heat dissipating coefficient, therefore enhancing the heat dissipating efficiency of the semiconductor chip 23 via the metal layer 20. The wiring layer 25 formed on the dielectric layer 24 comprises a plurality of conductive electrodes 25a, wherein the conductive electrodes 25a electrically connects the electrical connection pads 231a of the semiconductor chip 23.

Referring to FIG. 2F, the metal layer 20 is formed on the bottom side of the semiconductor chip 23 not connecting to the dielectric layer 24 in a similar way to that as illustrated in FIG. 2E. The wiring layer 25 formed on the surface of the dielectric layer 24 comprises a plurality of conductive electrodes 25a, wherein a portion of the conductive electrodes 25a electrically connects the electrical connection pads 231a of the semiconductor chip 23, and a portion of the conductive electrodes 25a are exposed from the surface without the semiconductor chip 23 for additionally connecting external electrical elements 29, thus flexibly using the space of the package structure and improving the electrical properties thereof. The semiconductor chip and the external electronic elements can be firstly formed, and the aforementioned dielectric layer, wiring layer, added wiring layer structure, conductive electrodes, solder mask layer, and electrical connection structure (e.g. solder balls) can be then formed on the semiconductor chip and external electronic elements.

The above embodiments can be cooperatively combined in accordance with different requirements to form various alternative embodiments.

### Second Embodiment

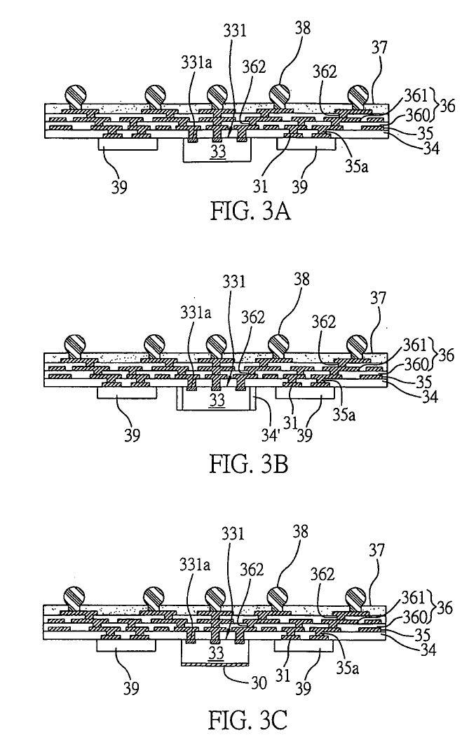

Referring to FIGS. 3A to 3C, the schematic sectional views of the flip-chip package structure with direct electrical connection to a semiconductor chip in accordance with a second embodiment of the present invention are illustrated. The second embodiment of the present invention is similar to the first embodiment, the main difference is that an electrode pad is formed on the lower surface of the dielectric layer, so that the semiconductor chip and the electrode pad are exposed to the outside for decreasing the overall height of the structure thereof, wherein the electrode pad is employed for further providing electrically connection to external electrical elements.

Referring to FIG. 3A, a second embodiment of the present invention is illustrated, which mainly comprises: at least a semiconductor chip 33, electrical connection pads 331a formed on an active surface 331 of the semiconductor chip 33; at least a dielectric layer 34 formed on the active surface 331 of the semiconductor chip 33, the area of the dielectric layer 34 being greater than that of the active surface 331, a plurality of electrode pads 31 formed on a side of the dielectric layer 34 which connects the semiconductor chip 33, the electrode pads 31 exposed from the surface of the dielectric layer 34; and at least a wiring layer 35 formed on a side of the dielectric layer 34 not connecting the semiconductor chip 33. The wiring layer 35 formed on the surface of the dielectric layer 34 comprises a plurality of conductive electrodes 35a, wherein some of the conductive electrodes 35a electrically connects the electrical connection pads 331a of the semiconductor chip 33, and some of the conductive electrodes 35a electrically connects the electrode pads 31 for further connecting external electrical elements 39, such as active elements or passive elements, on the dielectric layer 34, so as to electrically connecting the external electrical elements 39 to inner circuit via the exposed part of the conductive electrodes 35a, thus flexibly using the space of the package structure and improving the electrical property thereof.

An added wiring layer structure 36 can be further formed on the dielectric layer 34 and the wiring layer 35. The added wiring layer structure 36 comprises a dielectric layer 360, a wiring layer 361 formed on the dielectric layer 360 and a conductive blind via 362 extending through the dielectric layer 360 for connecting the wiring layer 361, and the added wiring layer structure 36 also electrically connects the wiring layer 35 via the conductive blind via 362. A solder mask layer 37 is formed on the outer surface of the added wiring layer structure 36, and the solder mask layer 37 defines a plurality of openings for exposing partial wiring layer on the outer surface of the added wiring layer structure 36 so that a plurality of conductive elements 38, such as solder balls, solder pads, pins or metal bumps, can be formed thereon to electrically connect the semiconductor chip 33 to the external devices.

It should be noted that the semiconductor chip 33 and the external electronic elements 39 can be firstly formed, and dielectric layer 34, wiring layer 35, added wiring layer structure 36, conductive electrodes 35a, solder mask layer 37, and electrical connection structure (e.g. solder balls) 38 can be then formed on the semiconductor chip 33 and external electronic elements 39.

Referring to FIG. 3B, which is similar to FIG. 3A, the main difference is that a thin dielectric layer 34′ is formed on the circumference of the semiconductor chip 33 for coating and securing the semiconductor chip 33 to the bottom of the dielectric layer 34, therefore preventing the semiconductor chip 33 from being damaged by external force. Electrode pads 31 of the dielectric layer 34 at the side that is connected with the semiconductor chip 33 can be employed for further connecting external devices on the surface of the dielectric layer 34, thus flexibly using the space of the package structure and improving the electrical property thereof.

Referring to FIG. 3C, which is similar to FIG. 3A, the main difference is that a metal layer 30 is formed on a bottom side of the semiconductor chip 33 not connecting to the dielectric layer 34, wherein the metal layer 30 is made of material with high heat dissipating coefficient, therefore enhancing the heat dissipating efficiency of the semiconductor chip 33 via the metal layer 30. The electrode pads 31 of the dielectric layer 34 at the side that is connected with the semiconductor chip 33 can be employed for further connecting external devices on the surface of the dielectric layer 34, thus flexibly using the space of the package structure and improving the electrical property thereof.

By employing the flip-chip package structure with direct electrical connection of semiconductor of the present invention, the semiconductor chip is exposed from the surface of the dielectric layer to efficiently dissipate heat generated by the operation of the semiconductor chip, therefore decreasing the overall height of the semiconductor structure. In addition, at least a wiring layer is directly formed on the active surface of the semiconductor chip in embodiments of the present invention, and the wiring layer structure electrically connects the electrical connection pads of the semiconductor chip via the conductive electrodes, and a plurality of conductive elements, such as solder balls, solder pads, pins or metal bumps, are formed on the outer surface of the circuit for connecting to external devices. Additionally, electrode pads are further formed on the dielectric layer at a side that is connected to the semiconductor chip, or the conductive electrodes of the dielectric layer are exposed for electrically connecting electronic elements (such as active or passive elements), so that the electronic elements electrically connect the semiconductor chip via the wiring layer and conductive electrode or via the wiring layer, the conductive electrode and electrode pads, thus flexibly using the space of the package structure and improving the electrical properties thereof.

Consequently, the present invention integrates the semiconductor chip and the added wiring layer structure to solve the problems of conventional semiconductor package technology and the problems of integration of the interfaces of semiconductor devices, simultaneously improving the product quality and yield rate for achieving better quality and reliability of packaging structures with embedded semiconductor chips.

It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. A flip-chip package structure with direct electrical connection of at least one semiconductor chip, comprising:
the semiconductor chip having an active surface and a non-active surface, and the active surface of the semiconductor chip comprising electrical connection pads;
at least a dielectric layer formed on the active surface of the semiconductor chip, the area of the dielectric layer being greater than that of the active surface, so that the non-active surface of the semiconductor chip is directly exposed; and
at least a wiring layer formed on a side of the dielectric layer not connected to the semiconductor chip, the wiring layer electrically connecting the electrical connection pads of the semiconductor chip via a plurality of conductive electrodes formed in the dielectric layer.

2. The flip-chip package structure as claimed in claim 1, further comprising an added wiring layer structure formed on the dielectric layer and the wiring layer.

3. The flip-chip package structure as claimed in claim 2, wherein the added wiring layer structure further comprises conductive elements on the surface thereof.

4. The flip-chip package structure as claimed in claim 3, wherein the conductive elements can be selected from the group consisting of solder balls, solder pads, pins and metal bumps.

5. The flip-chip package structure as claimed in claim 1, wherein the semiconductor chip can be selected from the group consisting of active elements and passive elements.

6. The flip-chip package structure as claimed in claim 1, wherein a plurality of conductive electrodes are exposed from a side of the dielectric layer connecting the semiconductor chip.

7. The flip-chip package structure as claimed in claim 6, wherein the conductive electrodes connect to at least an external electronic element.

8. The flip-chip package structure as claimed in claim 6, wherein the conductive electrodes electrically connect to an electrode pad for connecting to at least an external electronic element.

9. The flip-chip package structure as claimed in claim 7, wherein the at least one external electronic element can be at least one selected from the group consisting of active elements and passive elements.

10. The flip-chip package structure as claimed in claim 8, wherein the at least one external electronic element can be at least one selected from the group consisting of active elements and passive elements.

11. The flip-chip package structure as claimed in claim 1, wherein a thin dielectric layer is formed on the circumference of the semiconductor chip.

12. The flip-chip package structure as claimed in claim 6, wherein a thin dielectric layer is formed on the circumference of the semiconductor chip.

13. The flip-chip package structure as claimed in claim 8, wherein a thin dielectric layer is formed on the circumference of the semiconductor chip.

14. The flip-chip package structure as claimed in claim 1, wherein a metal layer is formed on a bottom surface of the semiconductor chip.

15. The flip-chip package structure as claimed in claim 6, wherein a metal layer is formed on a bottom surface of the semiconductor chip.

16. The flip-chip package structure as claimed in claim 8, wherein a metal layer is formed on a bottom surface of the semiconductor chip.
